(19) United States
(12) Patent Application Publication
(10) Pub. No.: US 2007/0141773 A1
(43) Pub. Date: Jun. 21, 2007

(54) Structure of semiconductor device and method of fabricating the same

(75) Inventor: Dae Kyeun Kim, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/639,587

(22) Filed: Dec. 15, 2006

(30) Foreign Application Priority Data
Dec. 16, 2005 (KR) 10-2005-0124418

(51) Int. Cl. H01L 21/8238; H01L 21/8242; H01L 21/4763

(52) U.S. Cl. 438/210; 438/250; 438/256; 438/592

(57) ABSTRACT

Disclosed are a structure of a semiconductor device and a method of manufacturing the same. The distance between gate electrodes and capacitor upper electrodes is reduced so that, when spacer insulating layers are etched to form sidewall spacers, spacer insulating layers remain between the gate electrodes and the capacitor upper electrodes so as not to expose the silicon substrate. Therefore, when a silicide mask pattern is formed (in order to form a self aligned silicide layer in a subsequent process), it is possible to improve the process margin. Therefore, it is possible to prevent the gate electrodes from being damaged due to contact hole etching, which may be caused by misalignment of the silicide mask pattern, and prevent defects such as current leakage between a gate and a capacitor, unlike in the conventional art. As a result, it is possible to improve the reliability and yield of the semiconductor device.

This application claims the benefit of Korean Application No. 10-2005-0124418, filed on Dec. 16, 2005, which is incorporated by reference herein in its entirety.

### BACKGROUND OF THE INVENTION

1. Field of the Invention

The present invention relates to a method of manufacturing a semiconductor device. More specifically, the present invention relates to a structure of the semiconductor device and a method of manufacturing the same, in which the distance between a gate and a capacitor is reduced and a spacer insulating layer remains therebetween to increase the process margin in forming a silicide mask pattern for a self aligned silicide layer.

2. Description of the Related Art

In a 1T-SRAM (a kind of semiconductor device, circuit or cell), one cell may include one transistor, unlike a common SRAM in which one cell typically includes six transistors. The 1T-SRAM is highly integrated and can be manufactured at low price, which are advantages of a DRAM. However, the 1T-SRAM generally operates fast (at a relatively high frequency, as compared with conventional DRAMs) with various functions, which are the advantages of the SRAM.

The schematic layout of the semiconductor device is illustrated in FIG. 1. The manufacturing method is illustrated in FIGS. 2A to 2F. FIGS. 2A to 2F are sectional views taken along line II-II of FIG. 1.

Hereinafter, a conventional method of manufacturing the semiconductor device will be described. First, as illustrated in FIGS. 1 and 2A, insulating layers 21a and 21b and conductive layers 22a and 22b are deposited on a silicon substrate 10, where an active region 11 and an isolation region 12 are formed. The insulating layers 21a and 21b and conductive layers 22a and 22b are etched in a desired pattern to form a gate and a capacitor. The patterned insulating layer becomes the gate insulating layer 21a and the capacitor dielectric layer 21b. The patterned conductive layer becomes the gate electrode 22a and the capacitor upper electrode 22b.

Then, low density source and drain regions (e.g., lightly doped source/drain extension regions, not shown) are formed by an ion implantation process. Then, as illustrated in FIG. 2B, spacer insulating layers 23 and 24 are deposited. The spacer insulating layer includes a nitride layer 23 and an oxide layer 24.

Then, as illustrated in FIG. 2C, the spacer insulating layers are entirely etched (i.e., blanket-etched or anisotropically etched)_to form sidewall spacers 23a and 24a. An ion implantation process forms high density source/drain regions (not shown) using the sidewall spacers 23a and 24a, gates 22a and capacitor upper electrodes 22b as masks.

Then, as illustrated in FIG. 2D, mask insulating layers are deposited and etched to form a silicide mask pattern 25. The silicide mask pattern 25 exposes a region in which a silicide layer is to be formed.

Then, as illustrated in FIG. 2E, a metal is deposited and annealed to selectively form a self aligned silicide layer 26. The silicide layer 26 is formed selectively on the gate electrodes 22a and on the active region of the silicon substrate 10 exposed by the silicide mask pattern 25.

Then, as illustrated in FIG. 2F, an interlayer insulating layer 27 is deposited and selectively etched to form contact holes 28a and 28b. The contact holes 28a and 28b are formed on or over the active region of the silicon substrate and the gate electrodes 22a where the silicide layers 26 are formed. Although not shown in the Figures, a contact hole is also formed over the capacitor upper electrodes 22b in order to connect the capacitor upper electrodes 22b to a ground potential.

In the conventional method of manufacturing the semiconductor device, the silicide mask pattern 25 enables selective formation of the silicide layer 26. However, when misalignment occurs due to insufficient process margin(s), the following problems may result.

FIGS. 3A and 3B are sectional views illustrating examples of defects that may be generated in the conventional method of manufacturing the semiconductor device.

When misalignment occurs during formation of the silicide mask pattern, a silicide mask pattern 25 may be partially formed on the gate electrode 22a as illustrated in FIG. 3A, or may partially expose the silicon substrate 10 between the gate electrode 22a and the capacitor upper electrode 22b as illustrated in FIG. 3B. Therefore, the silicide layer 26 may be only partially formed on the gate electrode 22a (31 of FIG. 3A) or may be partially formed on the silicide substrate 10 between the gate electrode 22a and the capacitor upper electrode 22b (32 of FIG. 3B). In the former case, the gate electrode 22a that is not covered with the silicide layer 26 is vulnerable to etching during a subsequent contact hole etching process. As a result, the gate electrode 22a may be damaged. In the latter case, the region in which the silicide layer 26 is formed can function as a path of current leakage.

### SUMMARY OF THE INVENTION

The present invention has been made to solve the above problems occurring in the related art, and therefore, it is an object of the present invention to provide a semiconductor device structure capable of improving process margin in processes involving a silicide mask pattern for a self aligned silicide layer and of improving reliability of and yields in manufacturing the semiconductor device.

According to one aspect of the present invention, there is provided a method of manufacturing a semiconductor device. The method includes the steps of (a) depositing and etching an insulating layer and a conductive layer on a silicon substrate to form a gate including a gate insulating layer and a gate electrode, and a capacitor including a capacitor dielectric layer and a capacitor upper electrode, (b) depositing and etching a spacer insulating layer to form sidewall spacers in a region between adjacent gate electrodes and a spacer insulating layer between the gate electrode and the capacitor upper electrode, (c) depositing and etching a mask insulating layer to form a silicide mask pattern that exposes the regions where silicide layers are to be formed, and (d) depositing and annealing a metal to selectively form a self aligned silicide layer on the silicon substrate and on the gate electrode exposed by the silicide mask pattern.

The process margin of the silicide mask pattern is improved due to the spacer insulating layer that remains between the gate electrode and the capacitor upper electrode.

In the method of manufacturing the semiconductor device, the distance between the gate electrode and the adjacent (or nearest) capacitor upper electrode is preferably ¼ to ¾ of the distance between adjacent gate electrodes. At this time, the distance between the gate electrode and the nearest capacitor upper electrode may be from 50 nm to 150 nm.

In one embodiment, the spacer insulating layer may comprise a nitride layer and an oxide layer, which can be sequentially deposited on the substrate, including the gate electrode(s). The oxide layer can be deposited to a thickness of 500 to 2,000 Å.

In a further embodiment, the silicide mask pattern can comprise a LP-TEOS (a silicon [di]oxide film formed by low-pressure chemical vapor deposition [CVD] from a feed gas containing tetraethyl orthosilicate [TEOS]) or PE-TEOS (a silicon [di]oxide film formed by plasma-enhanced CVD from a feed gas containing TEOS). In another embodiment, the metal for the self-aligned silicide layer can comprise a member selected from the group consisting of tantalum (Ta), cobalt (Co), nickel (Ni), and titanium (Ti).

On the other hand, the structure of a semiconductor device (which may be manufactured by one of the above methods) is also provided.

### BRIEF DESCRIPTION OF DRAWINGS

FIG. 1 is a schematic layout diagram of a conventional semiconductor device;

FIGS. 2A to 2F are sectional views illustrating the structure of the conventional semiconductor device and a method of manufacturing the same;

FIGS. 3A and 3B illustrate examples of defects that can be generated in the conventional semiconductor device;

FIG. 4 is a schematic layout diagram of a semiconductor device according to an embodiment of the present invention; and

FIGS. 5A to 5E are sectional views illustrating the structure of the semiconductor device according to the embodiment of the present invention and a method of manufacturing the same.

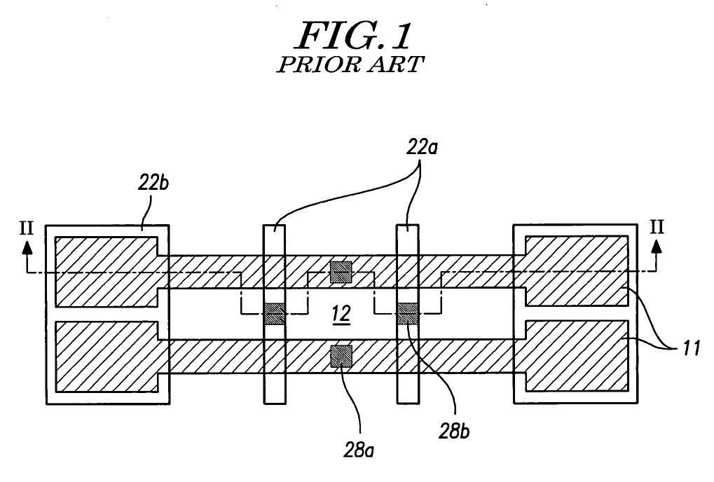

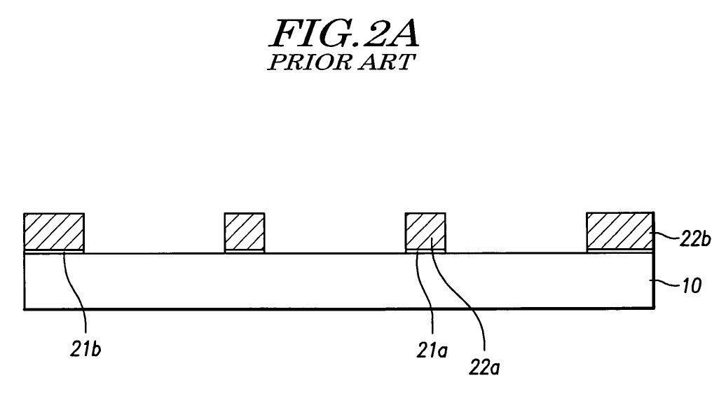

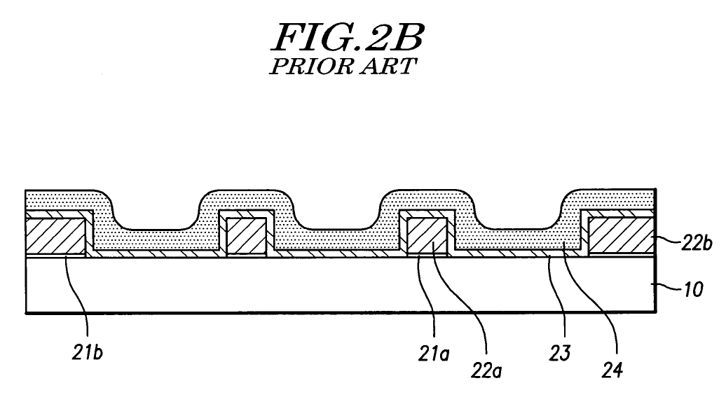

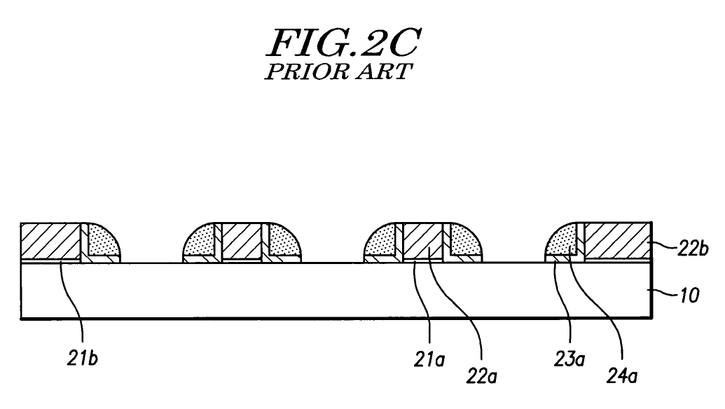

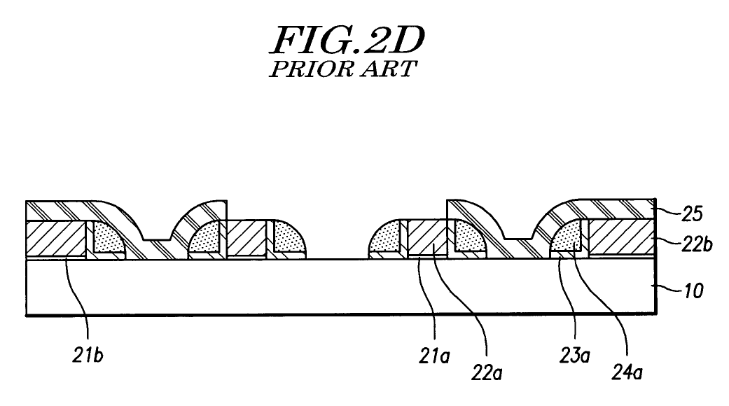

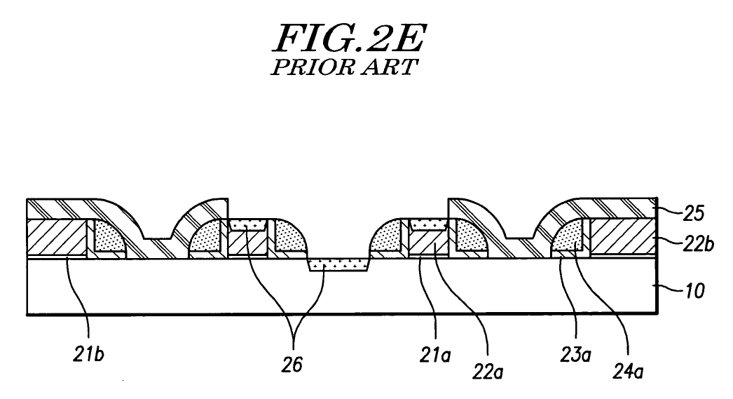

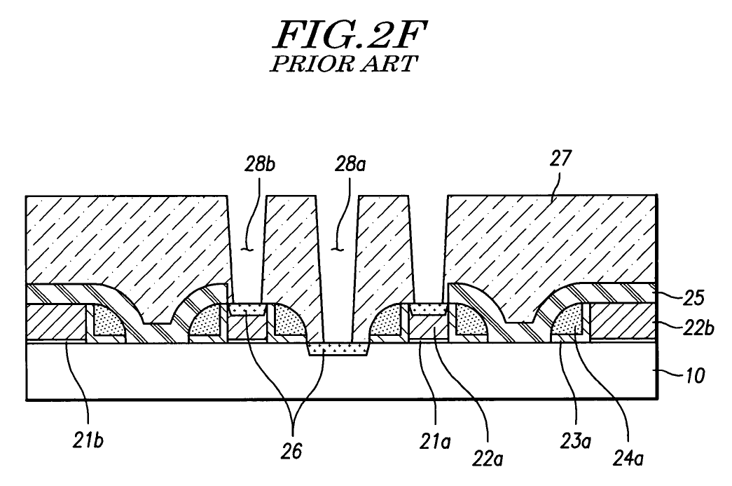

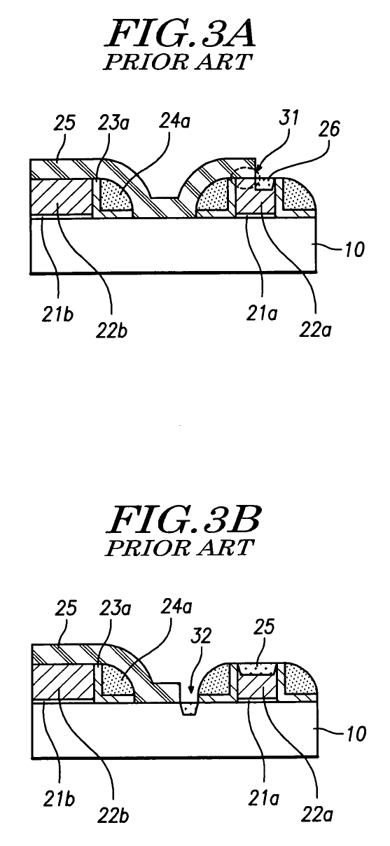

### DETAILED DESCRIPTION OF THE INVENTION

Preferred embodiments of the present invention will be described herein below with reference to the accompanying drawings.

In the following description of the present invention, some structures or manufacturing processes are omitted in order to avoid redundancy and to clarify the subject matter of the present invention. In the same manner, some of elements can be exaggerated, omitted or simplified in the drawings, and the elements in an actual device may have sizes different from those shown in the drawings, in practice. The same reference numerals generally represent the same elements, even if they are shown in different drawings.

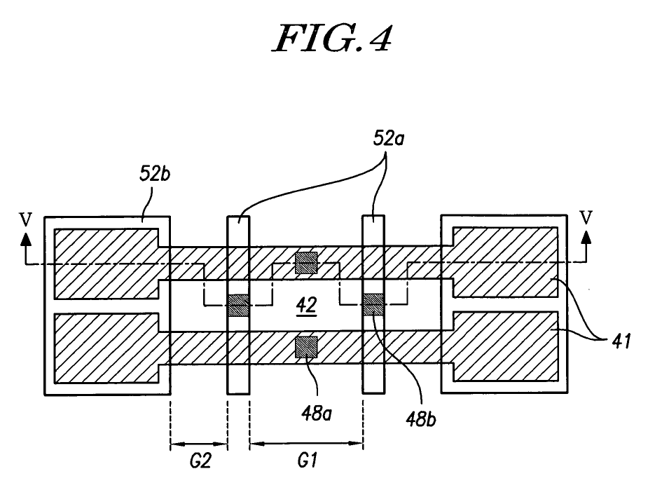

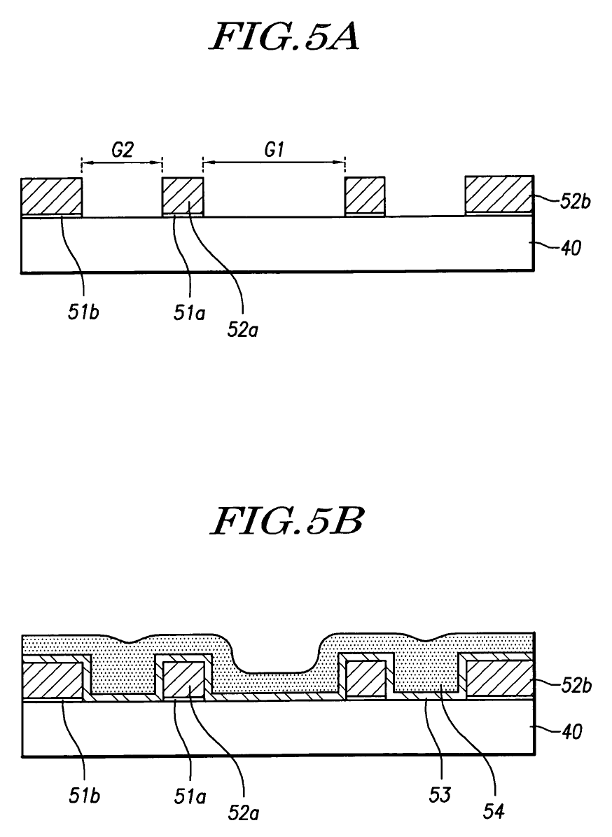

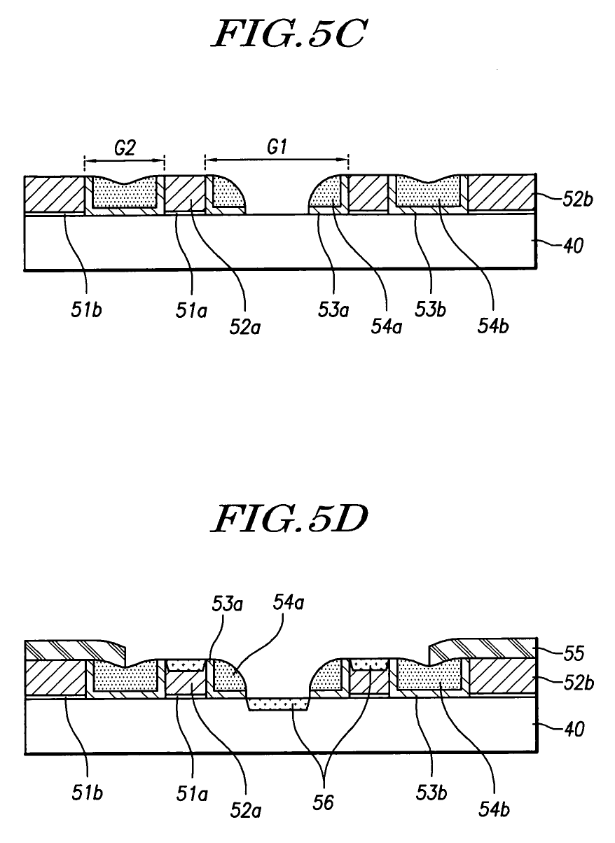

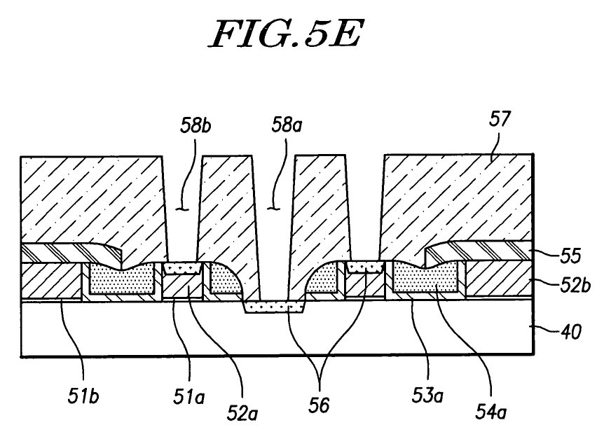

FIG. 4 is a schematic layout diagram of a semiconductor device according to an embodiment of the present invention. FIGS. 5A to 5E are sectional views illustrating the structure of the semiconductor device according to embodiments of the present invention and a method of manufacturing the same. FIGS. 5A to 5E are sectional views taken along the line V-V of FIG. 4.

Referring to FIG. 4, in the structure of the semiconductor device according to the present invention, the distance G2 between gate electrodes 52a and adjacent capacitor upper electrodes 52b (or the nearest borders or sidewalls thereof) is reduced in comparison with the conventional distance between the gate electrodes and the adjacent capacitor upper electrodes. In the conventional technology, the distance is similar to the distance between adjacent gate electrodes. However, the distance G2 is ¼ to ¾ of the distance (G1) between the gate electrodes 52a (e.g., the distance between the nearest borders or sidewalls of adjacent gate electrodes 52a). For example, when the distance G1 between the adjacent gate electrodes 52a is 200 nm, the distance between a gate electrode 52a and the nearest capacitor upper electrode 52b is from 50 to 150 nm.

In this manner, when the distance G2 between the gate electrodes 52a and the capacitor upper electrodes 52b is reduced, and when spacer insulating layers are entirely etched (e.g., etched back or anisotropically etched) to form sidewall spacers, the spacer insulating layer remains in the space between a gate electrode 52a and the nearest capacitor upper electrode 52b so that the silicon substrate between the two structures is not exposed. Therefore, when a subsequent silicide mask pattern is used to form a self aligned silicide layer, the process margin of the subsequent silicidation process (including the photolithographic patterning process for forming the silicide mask) is improved, thereby preventing or reducing the incidence of the problem(s) occurring in the conventional technology.

Hereinafter, the procedure for manufacturing a semiconductor device or structure will be described. The structure of the semiconductor device will become more apparent by describing the manufacturing procedure.

First, as illustrated in FIGS. 4 and 5A, after a gate insulating layer and a conductive layer are sequentially deposited on a silicon substrate 40 having an active region 41 and an isolation region 42 formed or defined therein, the insulating layer and the conductive layer are photolithographically masked and etched in a desired or predetermined pattern to form a gate 52a and 51a and a capacitor 52b and 51b. At this time, the patterned insulating layer becomes the gate insulating layer 51a and the capacitor dielectric layer 51b, and the patterned conductive layer becomes the gate electrodes 52a and the capacitor upper electrodes 52b. On the other hand, when the insulating layer 51a and 51b and the conductive layer 52a and 52b are etched, as described above, the distance G2 between the gate electrodes 52a and the capacitor upper electrodes 52a is about ¼ to ¾ of the distance G1 between the adjacent gate electrodes 52a.

Then, in order to form low density source and drain extension regions (not shown), an ion implantation process is performed using the gate electrodes 52a and the capacitor upper electrodes 52a as a mask. However, the low density implant in the substrate (e.g., between gate electrode 52a and adjacent capacitor upper electrode 52b) preferably contains a concentration of dopant sufficient to render the low density implant conductive under the operational conditions that require conductivity (e.g., a high logic level voltage is applied to gate electrode 52a and a charge representative of a digital “1” state is stored in the capacitor corresponding to upper electrode 52b). Thereafter, as illustrated in FIG. 5B, spacer insulating layers 53 and 54 are deposited. The spacer insulating layers may comprise a nitride layer 53 and an oxide layer 54. The oxide layer 54 comprises, for example, a TEOS layer (as described above), and may have a thickness of from about 500 to 2,000 Å, preferably about 800 to 1,500 Å. The nitride layer 53 comprises, for example, a silicon nitride layer, and may have a thickness of from about 100 to 500 Å, preferably about 200 to 400 Å.

Then, as illustrated in FIG. 5C, the spacer insulating layers 53 and 54 are entirely etched (e.g., blanket-etched, for example by a conventional etch back or anisotropic etch process, such as dry, plasma etching) to form sidewall spacers 53a and 54a. At this time, like in the conventional art, the sidewall spacers 53a and 54a are formed in the region G1 between the gate electrodes 52a. However, residual spacer insulating layers 53b and 54b remain in the region G2 between the gate electrodes 52a and the capacitor upper electrodes 52b so as to mask (i.e., not to expose) a silicon substrate 40. Then, the sidewall spacers 53a and 54a are used as masks during the ion implantation process for forming the high density source and drain regions (not shown).

After that, as illustrated in FIG. 5D, a mask insulating layer is deposited and etched to form a silicide mask pattern 55. The mask insulating layer may comprise LP-TEOS or PE-TEOS, and is preferably deposited to a thickness no less than 600 Å. The silicide mask pattern 55 exposes the region in which the silicide layer is to be formed. At this time, the process margin of the silicide mask patterns 55 is improved due to the spacer insulating layers 53b and 54b that reside between the gate electrodes 52a and the capacitor upper electrodes 52b.

Then, a metal is deposited and annealed to selectively form self aligned silicide layer 56. The metal may include tantalum (Ta), cobalt (Co), nickel (Ni), and/or titanium (Ti). The silicide layer 56 is selectively formed on the active region of the silicon substrate 40 exposed between the silicide mask patterns and on the gate electrodes 52a. Unreacted metal on structures other than exposed silicon can then be selectively removed, as is known in the art.

Next, as illustrated in FIG. 5E, an interlayer insulating layer 57 is deposited on the entire resulting structure, then is planarized (e.g., by chemical mechanical polishing). The insulating layer 57 may comprise one or more conventional insulating materials (e.g., silicon dioxide [e.g., USG or a TEOS film as described above], which may be doped with fluorine

or boron and/or phosphorous [BSG, PSG, or BPSG], silicon nitride, a silicon-rich oxide [SRO], a silicon oxycarbide [SiOC] which may be hydrogenated [SiOCH], etc.). A multi-layer insulator, such as a stacked silicon nitride/BPSG/USG/TEOS or a USG/FSG/USG stack (which may further comprise a lower and/or upper silicon nitride layer and/or an upper TEOS layer), is particularly suitable. Then, a photoresist is deposited thereon and patterned to form a contact hole mask, then the exposed insulating layer 57 is selectively etched to thus form contact holes 58a and 58b. The contact holes 58a and 58b are connected to the top of (and thus expose) the active region of the silicon substrate 40 and the tops of the gate electrodes 52a where the silicide layers 56 are formed. Although not shown in the Figures, a contact hole may also be formed over the capacitor upper electrodes 52b in order to connect the capacitor upper electrodes 52b to a ground potential. Then, contact plug and metal wiring processes (and processes subsequent thereto) are performed.

As described above, according to the present invention, the distance between the gate electrodes and the capacitor upper electrodes is reduced so that, when the spacer insulating layers are etched to form the side spacers, the spacer insulating layers remain between the gate electrodes and the capacitor upper electrodes so as not to expose the silicon substrate. Therefore, when the silicide mask pattern is formed in order to form a self aligned silicide layer in a subsequent process, it is possible to improve the process margin. Therefore, it is possible to reduce or prevent damage to the gate electrodes from subsequent contact hole etching, which may result the misalignment of the silicide mask pattern, and reduce or prevent defects such as current leakage between the gate and the capacitor, unlike in the conventional art. As a result, it is possible to improve the reliability and yield of the semiconductor device.

While the invention has been shown and described with reference to certain preferred embodiments thereof, it will be understood by those skilled in the art that various changes in form and details may be made therein without departing from the spirit and scope of the invention as defined by the appended claims.

What is claimed:

1. A method of manufacturing a semiconductor device, the method comprising the steps of:
depositing and etching an insulating layer and a conductive layer on a silicon substrate to form (i) a gate comprising a gate insulating layer and a gate electrode and (ii) a capacitor comprising a capacitor dielectric layer and a capacitor upper electrode;
depositing and etching a spacer insulating layer to form sidewall spacers in a region between adjacent gate electrodes and to form a spacer insulating layer between the gate electrode and the capacitor upper electrode;
depositing and etching a mask insulating layer to form a silicide mask pattern that exposes a silicide region; and
depositing and annealing a metal to selectively form a self aligned silicide layer on the silicon substrate and on the gate electrode exposed by the silicide mask pattern.

2. The method of claim 1, wherein a distance between the gate electrode and the capacitor upper electrode is ¼ to ¾ of a distance between the adjacent gate electrodes.

3. The method of claim 2, wherein the distance between the gate electrode and the capacitor upper electrode is from 50 nn to 150 nm.

4. The method of claim 1, wherein the spacer insulating layer comprises a nitride layer and an oxide layer.

5. The method of claim 4, wherein depositing the spacer insulating layer comprises depositing the nitride layer, then depositing the oxide layer.

6. The method of claim 4, wherein the oxide layer has a thickness of from 500 Å to 2,000 Å.

7. The method of claim 1, wherein the silicide mask pattern includes LP-TEOS or PE-TEOS.

8. The method of claim 1, wherein the metal includes a member selected from the group consisting of tantalum (Ta), cobalt (Co), nickel (Ni), and titanium (Ti).

9. The method of claim 1, comprising forming a plurality of gates and a plurality of capacitors.

10. The method of claim 1, wherein depositing and etching the silicide mask pattern has an improved process margin due to the spacer insulating layer.

11. A semiconductor device structure manufactured by a method as claimed in claim 1.

12. A semiconductor device, comprising:
a semiconductor substrate;
a plurality of gates on the semiconductor substrate, each gate comprising a gate insulating layer and a gate electrode;
a plurality of capacitors on the semiconductor substrate, each capacitor comprising a capacitor dielectric layer and a capacitor upper electrode;
sidewall spacers in a region between adjacent gate electrodes;
a spacer insulating layer between one of the gate electrodes and an adjacent capacitor upper electrode; and
a self aligned metal silicide layer on the silicon substrate and on the gate electrodes.

13. The semiconductor device of claim 12, wherein a distance between the gate electrode and the adjacent capacitor upper electrode is ¼ to ¾ of a distance between the adjacent gate electrodes.

14. The semiconductor device of claim 12, wherein the distance between the gate electrode and the adjacent capacitor upper electrode is from 50 nm to 150 nm.

15. The semiconductor device of claim 12, wherein each of the spacer and the spacer insulating layer comprises a nitride layer and an oxide layer.

16. The semiconductor device of claim 15, wherein each of the spacer and the spacer insulating layer comprises the oxide layer on the nitride layer.

17. The semiconductor device of claim 15, wherein the oxide layer has a thickness of from 500 Å to 2,000 Å.

18. The semiconductor device of claim 12, wherein a metal of the metal silicide includes a member selected from the group consisting of tantalum (Ta), cobalt (Co), nickel (Ni), and titanium (Ti).

19. The semiconductor device of claim 12, wherein depositing and etching the silicide mask pattern has an improved process margin due to the spacer insulating layer.
